(19) United States
(12) Patent Application Publication
(10) Pub. No.: US 2026/0088788 A1
(43) Pub. Date: Mar. 26, 2026

(54) VARIABLE GAIN AMPLIFIER AND OPERATION METHOD THEREOF

(71) Applicant: Industrial Technology Research Institute, Hsinchu (TW)

(72) Inventors: Jeng-Han Tsai, Taipei City (TW); Ying-Chen Chang, Taoyuan City (TW); Ping-Hsun Wu, Taoyuan City (TW)

(73) Assignee: Industrial Technology Research Institute, Hsinchu (TW)

(21) Appl. No.: 18/893,981

(22) Filed: Sep. 24, 2024

(51) Int. Cl. H03G 3/30; H03F 3/19

(52) U.S. Cl. CPC H03G 3/3036; H03F 3/19; H03F 2200/451; H03G 2201/103

(57) ABSTRACT

A variable gain amplifier includes first and second stage common-source (CS) amplifiers and a first transformer. The second stage CS amplifier includes a differential circuit and a current steering circuit. The differential circuit and the current steering circuit are coupled to a common connecting node, and the current steering circuit draws at least part of a current flowing through the differential circuit from the common connecting node. The first transformer includes primary and secondary sides. A first terminal of the primary side is coupled to an output terminal of the first stage CS amplifier, and a second terminal of the primary side is coupled to the common connecting node. A first terminal of the secondary side is coupled to a first differential input terminal of the differential circuit, and a second terminal of the secondary side is coupled to a second differential input terminal of the differential circuit.

### BACKGROUND

### Technical Field

The present disclosure relates to a variable gain amplifier, and particularly relates to a variable gain amplifier and an operation method thereof.

### Related Art

With the development of wireless communication technology, phased array antennas have been widely used in fifth-generation mobile communication (5G) systems. Generally speaking, the variable gain amplifier in the phased array antenna has to have a large enough adjustable gain range, low noise figure, and low phase variation characteristics under different gains. In order to realize the function of adjustable gain, conventional variable gain amplifiers usually adopt an amplifier architecture of the cascode configuration. However, the amplifier architecture of the cascode configuration has a higher noise figure than the amplifier in the common source stage configuration. Therefore, conventional phased array antenna systems usually require the addition of a low-noise amplifier before the variable gain amplifier to reduce the noise figure of the radio frequency receiving link.

In addition, conventional variable gain amplifiers are usually affected by parasitic capacitance effects, which causes the phases of multiple radio frequency links to change when the gain is adjusted. Therefore, how to provide a variable gain amplifier with low noise figure and low phase variation characteristics has become an important issue in the field of wireless communications.

### SUMMARY OF INVENTION

The present invention provides a variable gain amplifier and an operation method thereof, which can adjust the gain of the amplifier through an analog interface or a digital interface, and has low noise figure and low phase variation characteristics.

An embodiment of the present disclosure provides a variable gain amplifier. The variable gain amplifier includes a first stage common-source (CS) amplifier, a second stage CS amplifier, and a first transformer. The second stage CS amplifier includes a differential circuit and a current steering circuit. The differential circuit and the current steering circuit are coupled to a common connecting node, and the current steering circuit draws at least part of a current flowing through the differential circuit from the common connecting node. The first transformer has a primary side and a secondary side. The first terminal of the primary side is coupled to the output terminal of the first stage CS amplifier, and the second terminal of the primary side is coupled to the common connecting node. The first terminal of the secondary side is coupled to the first differential input terminal of the differential circuit, and the second terminal of the secondary side is coupled to the second differential input terminal of the differential circuit.

Another embodiment of the present disclosure provides an operation method of a variable gain amplifier. The variable gain amplifier includes a first stage CS amplifier, a second stage CS amplifier, and a first transformer. The first transformer is coupled between the first stage CS amplifier and the second stage CS amplifier. The operation method includes: configuring a differential circuit and a current steering circuit in the second stage CS amplifier, in which the differential circuit and the current steering circuit are coupled to a common connecting node, and the common connecting node is a virtual ground node; drawing at least part of a current flowing through the differential circuit from the common connecting node using the current steering circuit; and changing a gain of the variable gain amplifier according to a current amount drawn by the current steering circuit.

Based on the above, in various embodiments of the present disclosure, the variable gain amplifier adopts a two-stage common source amplifier circuit architecture, so the variable gain amplifier of the present disclosure has a lower noise figure compared to the variable gain amplifier structure of the cascode configuration. In addition, the second stage CS amplifier of the present disclosure is configured with the differential circuit and the current steering circuit, and the differential circuit and the current steering circuit are jointly coupled to the virtual ground node. In this way, the current steering circuit of the present disclosure can draw at least part of the current flowing through the differential circuit from the virtual ground node, and change the gain of the variable gain amplifier according to the current amount drawn by the current steering circuit. Furthermore, the present disclosure can also eliminate the parasitic capacitance effect generated by the transistor in the second stage CS amplifier by adding a capacitor (or a neutralizing capacitor) between differential pair transistors in the second stage CS amplifier. Therefore, the variable gain amplifier of the present invention can achieve low phase variations under different gains.

In order to make the above-mentioned features and advantages of the present disclosure more comprehensible, embodiments are given below and described in detail with reference to the accompanying drawings.

### BRIEF DESCRIPTION OF THE DRAWINGS

FIG. 1 is a block diagram of a variable gain amplifier according to an embodiment of the present disclosure.

FIG. 2 is a flow chart of an operation method of a variable gain amplifier according to an embodiment of the present disclosure.

FIG. 3A is a schematic circuit diagram illustrating the variable gain amplifier in FIG. 1 according to an embodiment of the present disclosure.

FIG. 3B is a schematic circuit diagram illustrating the variable gain amplifier in FIG. 1 according to another embodiment of the present disclosure.

FIG. 4 illustrates a measurement result and a simulation result of a noise figure of the variable gain amplifier in FIG. 3A according to an embodiment of the present disclosure.

FIG. 5A illustrates measurement results and simulation results of S-parameters of the variable gain amplifier in FIG. 3A according to an embodiment of the present disclosure.

FIG. 5B illustrates measurement results and simulation results of the S-parameters of the variable gain amplifier in FIG. 3B under different gains according to an embodiment of the present disclosure.

FIG. 6 illustrates measurement results and simulation results of a gain control range of the variable gain amplifier in FIG. 3A according to an embodiment of the present disclosure.

FIG. 7 illustrates gains and phase variations of the variable gain amplifier in FIG. 3B in different digital states according to an embodiment of the present disclosure.

### DESCRIPTION OF THE EMBODIMENTS

The word “coupled (or connected)” used throughout the specification of the application (including the appended claims) can refer to any direct or indirect means of connection. For example, if a first device is described as being coupled (or connected) to a second device, then it should be interpreted to mean that the first device may be directly connected to the second device, or that the first device may be indirectly connected to the second device through other devices or some means of connection. The terms “first,” “second,” and similar designations mentioned throughout the specification of the application (including the appended claims) are used to name elements or to distinguish different embodiments or scopes; the terms are not intended to limit the upper limit or lower limit of the number of elements and are not to limit the order of elements. Additionally, wherever possible, elements/components/steps using the same reference numerals are used in the drawings and embodiments to represent the same or similar parts. Elements/components/steps using the same numerals or the same terms in different embodiments can refer to the relevant descriptions of each other.

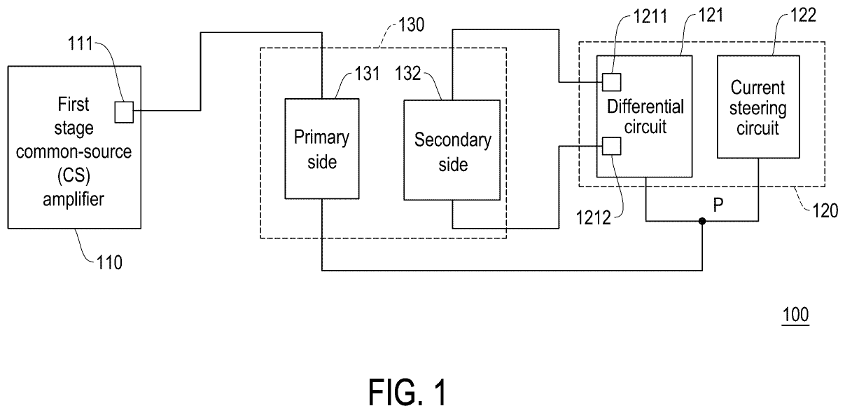

FIG. 1 is a block diagram of a variable gain amplifier according to an embodiment of the present disclosure. Referring to FIG. 1, a variable gain amplifier 100 includes a first stage common-source (CS) amplifier 110, a second stage CS amplifier 120, and a transformer 130. The second stage CS amplifier 120 includes a differential circuit 121 and a current steering circuit 122. The differential circuit 121 and the current steering circuit 122 are coupled to a common connecting node P, and the current steering circuit 122 may draw at least part of a current flowing through the differential circuit 121 from the common connecting node P. The transformer 130 has a primary side 131 and a secondary side 132. The first terminal of the primary side 131 of the transformer 130 is coupled to an output terminal 111 of the first stage CS amplifier 110, and the second terminal of the primary side 131 of the transformer 130 is coupled to the common connecting node P. The first terminal of the secondary side 132 of the transformer 130 is coupled to a first differential input terminal 1211 of the differential circuit 121, and the second terminal of the secondary side 132 of the transformer 130 is coupled to a second differential input terminal 1212 of the differential circuit 121.

In the embodiment of FIG. 1, in order for the second stage CS amplifier 120 to have a current steering mechanism, the present disclosure adds a single-ended to differential transformer 130 between the first stage CS amplifier 110 and the second stage CS amplifier 120, and the second stage CS amplifier 120 operates in a differential mode. Thus, the common connecting node P of both the differential circuit 121 and the current steering circuit 122 may become a virtual ground node. As a result, the current flowing through the differential circuit 121 and the current flowing through the current steering circuit 122 can be collected into the common connecting node P, and the collected current may flow through the first stage CS amplifier 110 through the primary side 131 of the transformer 130. Consequently, the current steering function could be realized in the architecture of the two-stage common source amplifier circuit.

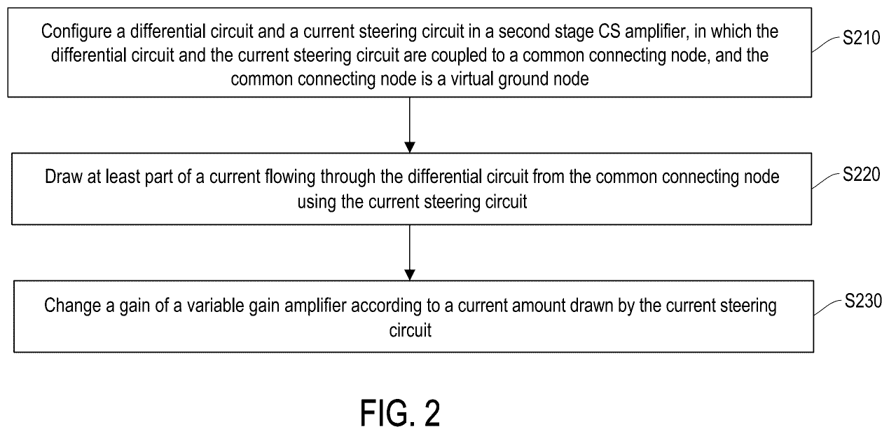

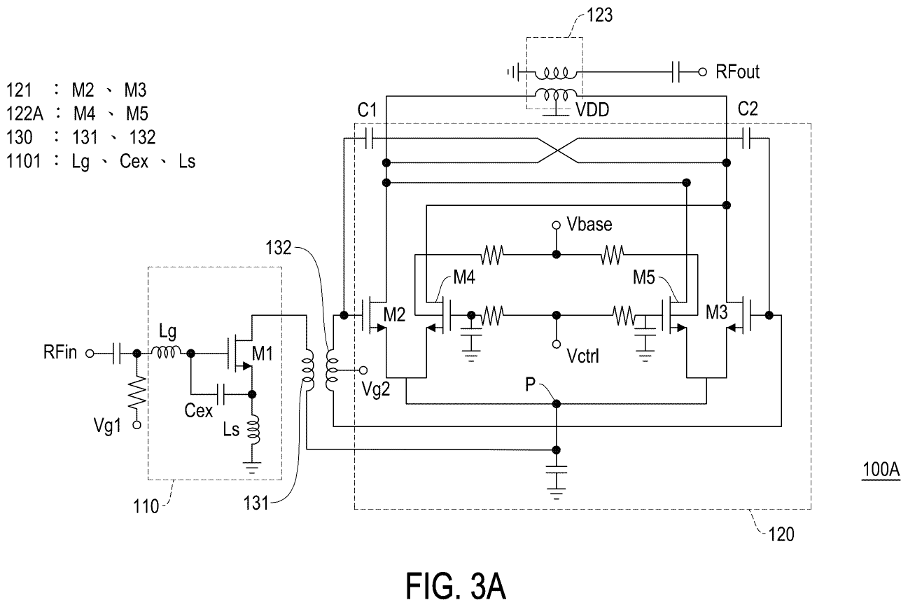

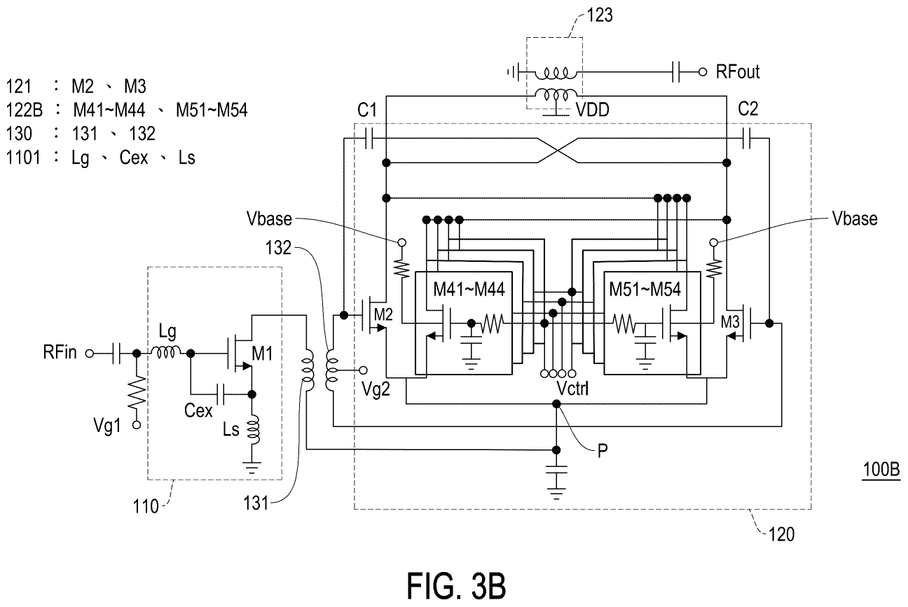

FIG. 2 is a flow chart of an operation method of a variable gain amplifier according to an embodiment of the present disclosure. FIG. 3A is a schematic circuit diagram illustrating the variable gain amplifier in FIG. 1 according to an embodiment of the present disclosure. Referring to FIG. 2 and FIG. 3A, in Step S210, a differential circuit 121 and a current steering circuit 122A may be configured in the second stage CS amplifier 120 of the variable gain amplifier 100A. For example, the differential circuit 121 in FIG. 3A may include a transistor M2 and a transistor M3. The first terminal of the transistor M2 is coupled to the common connecting node P. The control terminal of the transistor M2 may serve as the first differential input terminal of the differential circuit 121 (that is, 1211 in FIG. 1), and the second terminal of the transistor M2 may serve as the first output terminal of the differential circuit 121. The first terminal of the transistor M3 is coupled to the common connecting node P. The control terminal of the transistor M3 may serve as the second differential input terminal of the differential circuit 121 (that is, 1212 in FIG. 1), and the second terminal of the transistor M3 may be used as the second output terminal of the differential circuit 121. In addition, by adding the single-ended to differential transformer 130 between the first stage CS amplifier 110 and the second stage CS amplifier 120, the common connecting node P may be made into the virtual ground node.

Referring to FIG. 3A again, the current steering circuit 122A may include a transistor M4 and a transistor M5. The first terminal of the transistor M4 is coupled to the common connecting node P, the control terminal of the transistor M4 is coupled to a control voltage Vctrl, and the second terminal of the transistor M4 is coupled to the second terminal of the transistor M3. The first terminal of the transistor M5 is coupled to the common connecting node P, the control terminal of the transistor M5 is coupled to the control voltage Vctrl, and the second terminal of the transistor M5 is coupled to the second terminal of the transistor M2. In the embodiment of FIG. 3A, the transistors M2 to M5 are presented as N-type field effect transistors for illustrative purposes only and are not intended to limit the present disclosure. In other embodiments, the transistors M2 to M5 may also be P-type transistors. In addition, the transistors M2 to M5 may also be bipolar transistors or heterobipolar junction transistors, but are not limited thereto.

Referring to FIG. 2 and FIG. 3A, in Step S220, the current steering circuit 122A may draw at least part of the current flowing through the differential circuit 121 from the common connecting node P. FIG. 3A shows the use of an analog control interface to adjust the gain of the variable gain amplifier 100A. For example, the current steering circuit 122A may receive the control voltage Vctrl, and adjust the amount of the current drawn by the current steering circuit 122A according to the amount of the control voltage Vctrl, thereby changing the amount of the current flowing through the differential circuit 121. In Step S230, the present disclosure can change the gain of the variable gain amplifier 100A according to the current amount drawn by the current steering circuit 122A.

In detail, when the transistor M4 and the transistor M5 are not turned on by the control voltage Vctrl, the DC current output by the transistor M1 flows through the transistor M2 and the transistor M3. At this time, the variable gain amplifier 100A has the maximum gain. When the control voltage Vctrl increases to a voltage value that can turn on the transistor M4 and the transistor M5, part of the DC current output by the transistor M1 flows through the transistor M4 and the transistor M5, causing the current flowing through the transistor M2 and the transistor M3 to decrease, and at this time, the gain of the variable gain amplifier 100A is reduced. Therefore, the present disclosure could adjust the magnitude of the gain of the variable gain amplifier 100A by controlling how much current is drawn from main current paths (the transistor M2 and the transistor M3) by auxiliary current paths (the transistor M4 and the transistor M5).

In the embodiment of FIG. 3A, the first stage CS amplifier 110 includes a transistor M1 and an input matching network 1101. The input matching network 1101 includes an inductor Lg, a matching capacitor Cex, and an inductor Ls. The input terminal of the first stage CS amplifier 110 may receive a radio frequency input signal RFin and a bias voltage Vg1. The inductor Lg is coupled between the input terminal of the first stage CS amplifier and the control terminal of the transistor M1. The matching capacitor Cex is coupled between the control terminal of the transistor M1 and the first terminal of the transistor M1. The inductor Ls is coupled between the second terminal of the transistor M1 and a ground terminal. The input matching network 1101 may be used to implement noise matching and input conjugate matching. The second terminal of the transistor M1 may serve as the output terminal of the first stage CS amplifier 110 (that is, 111 in FIG. 1).

In the embodiment of FIG. 3A, the transistor M1 is presented as an N-type field effect transistor for illustrative purposes only and is not intended to limit the present disclosure. In other embodiments, the transistor M1 may also be a P-type transistor. In addition, the transistor M1 may also be a bipolar transistor or a heterobipolar junction transistor. According to the design requirements, the inter-stage matching network between the first stage CS amplifier 110 and the second stage CS amplifier 120, inter-stage matching may also be achieved through the inductance values of the primary side 131 and the secondary side 132 of the transformer 130, the turns ratio between the primary side 131 and the secondary side 132, or the coupling amount between the primary side 131 and the secondary side 132. In addition, the center tap end of the secondary side 132 of the transformer 130 may provide a bias voltage Vg2 to the control terminals of the transistor M2 and the transistor M3, and the center tap end of the primary side of the transformer 123 may provide an operating voltage VDD to the transistor M2 and the transistor M3. The output of the second stage CS amplifier 120 may convert the differential output into a single-ended output through the transformer 123, allowing the radio frequency output signal RFout to be provided to the next stage circuit (not shown).

Generally speaking, the phase variation of the variable gain amplifier under different gain states is positively related to the parasitic capacitance value of the transistor in the variable gain amplifier. Therefore, in the embodiment of FIG. 3A, the present disclosure may eliminate the parasitic capacitance values of the multiple transistors (that is, M2, M3, M4, and M5) in the second stage CS amplifier 120 by adding capacitors at specific positions in the second stage CS amplifier 120, in order to enable the variable gain amplifier 100A to achieve low phase variations at different gains. As shown in FIG. 3A, the second stage CS amplifier 120 further includes a capacitor C1 and a capacitor C2. The first terminal of the capacitor C1 is coupled to the control terminal of the transistor M2, and the second terminal of the capacitor C1 is coupled to the second terminal of the transistor M3 and the second terminal of the transistor M4. The first terminal of the capacitor C2 is coupled to the control terminal of the transistor M3, and the second terminal of the capacitor C2 is coupled to the second terminal of the transistor M2 and the second terminal of the transistor M5. Since the capacitor C1 and the capacitor C2 could eliminate the parasitic capacitance values of the multiple transistors (that is, M2, M3, M4, and M5) in the second stage CS amplifier 120, the variable gain amplifier 100A achieves low phase variations at different gains, so the capacitor C1 and the capacitor C2 may also be called neutralizing capacitors.

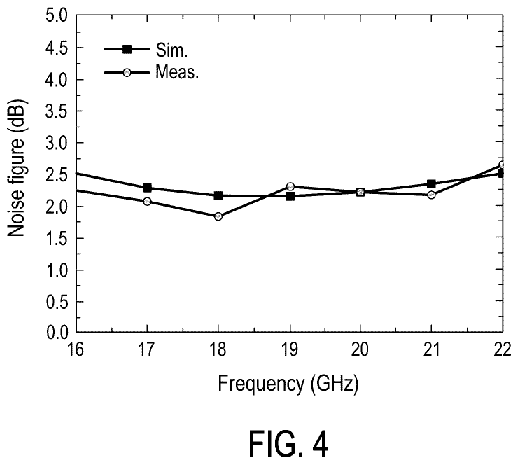

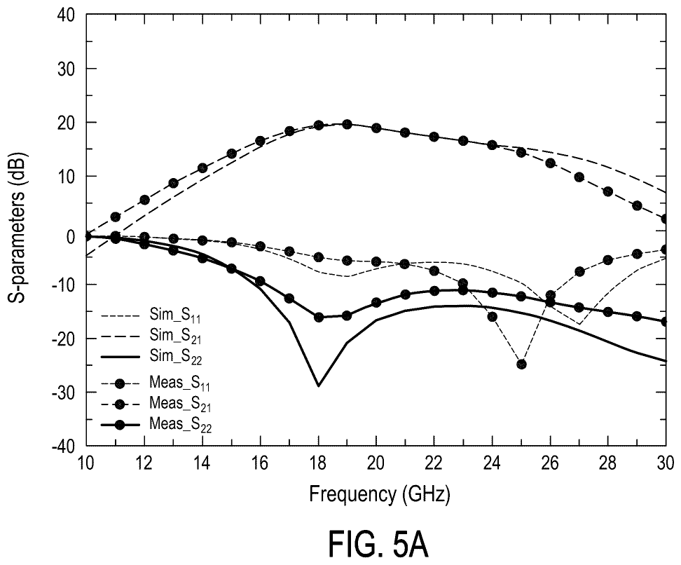

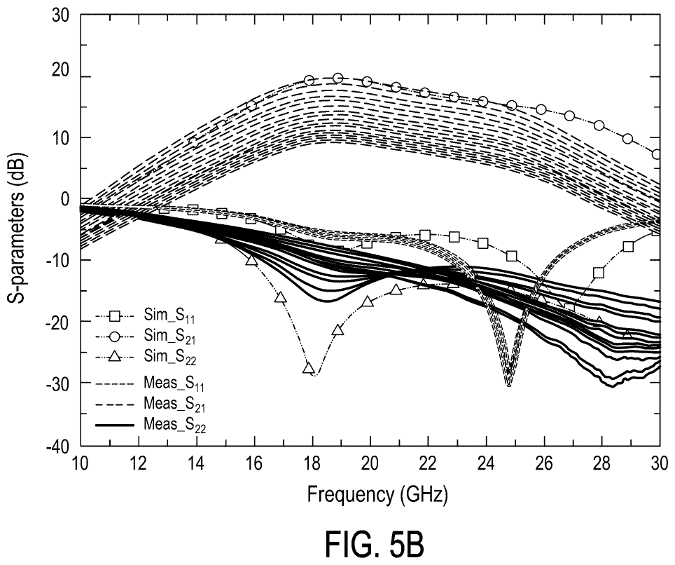

FIG. 4 illustrates a measurement result and a simulation result of a noise figure of the variable gain amplifier in FIG. 3A according to an embodiment of the present disclosure. As shown in FIG. 4, the variable gain amplifier 100A in FIG. 3A may maintain a noise figure of less than 2.5 dB in the frequency range of 17 to 21 GHz. Therefore, the variable gain amplifier 100A of the present disclosure could be used to replace the conventional receiver architecture of a phased array transceiver that requires a variable gain amplifier and another low noise amplifier. FIG. 5A illustrates measurement results and simulation results of S-parameters of the variable gain amplifier in FIG. 3A according to an embodiment of the present disclosure. It may be seen from the S21 parameter in FIG. 5A that the variable gain amplifier 100A in FIG. 3A could achieve a gain of more than 15 dB in the frequency range of 18 to 25 GHz.

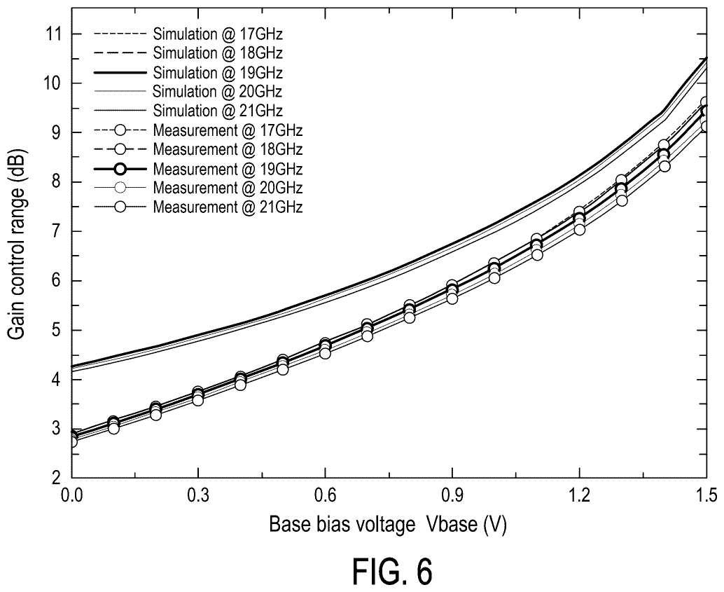

In the embodiment of FIG. 3A, the present disclosure may also apply a base bias voltage Vbase to the second stage CS amplifier 120 in the variable gain amplifier 100A, which enables the variable gain amplifier 100A to provide sufficient gain control range when operating at low voltage (for example: VDD is less than or equal to 1 volt). For example, the current steering circuit 122A may apply the base bias voltage Vbase to body terminals of both the transistor M4 and the transistor M5 to increase the current amounts drawn by both the transistor M4 and the transistor M5. In this way, the variable gain amplifier 100A could provide sufficient gain control range even under low voltage operation (for example: VDD is less than or equal to 1 volt). In addition, it should be noted that the body terminals of the transistor M4 and the transistor M5 are different from the first terminals (source terminals) of both the transistor M4 and the transistor M5, and are also different from the second terminals (drain terminals) of both the transistor M4 and the transistor M5. FIG. 6 illustrates measurement results and simulation results of a gain control range of the variable gain amplifier in FIG. 3A according to an embodiment of the present disclosure. As shown in FIG. 6, the variable gain amplifier 100A in FIG. 3A could achieve a variable gain range of more than 9 dB when the base bias voltage Vbase is 1.5V.

The present disclosure may also use a digital control interface to adjust the gain of the variable gain amplifier. FIG. 3B is a schematic circuit diagram illustrating the variable gain amplifier in FIG. 1 according to another embodiment of the present disclosure. The difference between FIG. 3B and FIG. 3A is that a current steering circuit 122B in a variable gain amplifier 100B in FIG. 3B includes a transistor group formed by a plurality of sub-transistors M41 to M44 and a transistor group formed by a plurality of sub-transistors M51 to M54. The first terminal of each sub-transistor among the plurality of sub-transistors M41 to M44 is coupled to the common connecting node P, the control terminal of each sub-transistor among the plurality of sub-transistors M41 to M44 is coupled to a digital control signal Vctrl, and the second terminal of each sub-transistor among the plurality of sub-transistors M41 to M44 is coupled to the second terminal of the transistor M3. The first terminal of each sub-transistor among the plurality of sub-transistors M51 to M54 is coupled to the common connecting node P, the control terminal of each sub-transistor among the plurality of sub-transistors M51 to M54 is coupled to the digital control signal Vctrl, and the second terminal of each sub-transistor among the plurality of sub-transistors M51 to M54 is coupled to the second terminal of the transistor M2.

In the embodiment of FIG. 3B, the current steering circuit 122B may use the digital control signal Vctrl (such as a digital code) to individually control the conduction state of each sub-transistor M41 to M44 and M51 to M54, which allows the current steering circuit 122B to draw currents of different current values from the common connecting node P, thereby adjusting the gain of the variable gain amplifier 100B. In addition, the current steering circuit 122B may further apply the base bias voltage Vbase to the body terminal of each sub-transistor M41 to M44 and M51 to M54 to increase the current amounts drawn by the sub-transistors M41 to M44 and M51 to M54. In this way, the variable gain amplifier 100B could provide a sufficient gain control range even under low voltage operation (for example: VDD is less than or equal to 1 volt). In addition, it should be noted that the body terminal of each sub-transistor M41 to M44 and M51 to M54 is different from the first terminal (source terminal) of each sub-transistor M41 to M44 and M51 to M54, and is also different from the second terminal (drain terminal) of each sub-transistor M41 to M44 and M51 to M54.

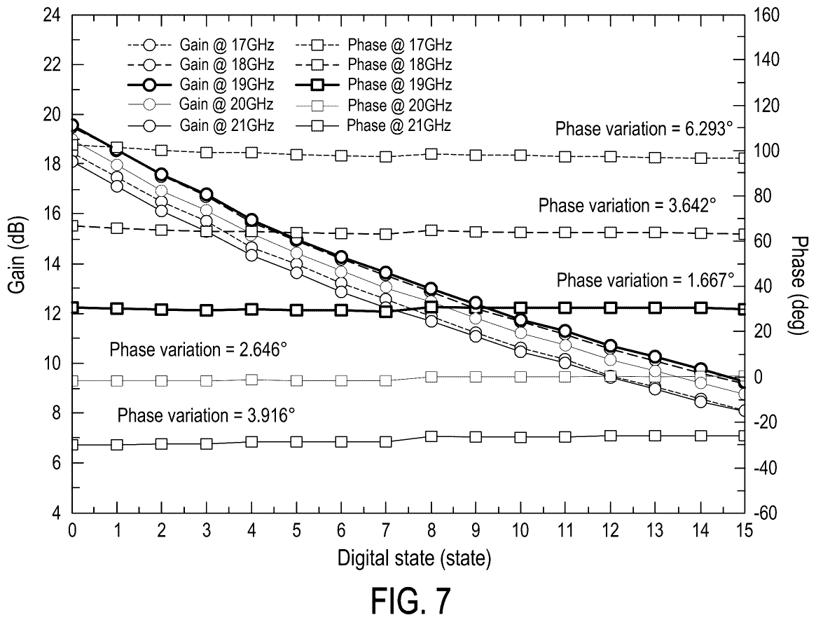

In addition, since the gain of the variable gain amplifier 100B could be adjusted through the digital control signal Vctrl in FIG. 3B, the complexity of the system control can be further reduced. FIG. 5B illustrates measurement results and simulation results of the S-parameters of the variable gain amplifier in FIG. 3B under different gains according to an embodiment of the present disclosure. As shown in the S21 parameter in FIG. 5B, under the control of the digital control signal Vctrl, the variable gain amplifier 100B in FIG. 3B could achieve a gain of more than 15 dB in the frequency range of 18 to 25 GHz. FIG. 7 illustrates gains and phase variations of the variable gain amplifier in FIG. 3B in different digital states according to an embodiment of the present disclosure. As shown in FIG. 7, the variable gain amplifier 100B in FIG. 3B could achieve a gain of more than 8 dB and maintain low phase variation characteristics in sixteen digital states. Therefore, the variable gain amplifier in FIG. 3B is suitable for application as a beamformer in a phased array antenna system.

In summary, in the embodiments of the present disclosure, the variable gain amplifier adopts the two-stage common source amplifier circuit architecture, so the variable gain amplifier of the present disclosure has a lower noise figure compared to the variable gain amplifier structure of the cascode configuration. In addition, the second stage CS amplifier of the present disclosure is configured with the differential circuit and the current steering circuit, and the differential circuit and the current steering circuit are jointly coupled to the virtual ground node. In this way, the current steering circuit of the present disclosure can draw at least part of the current flowing through the differential circuit from the virtual ground node, and change the gain of the variable gain amplifier according to the current amount drawn by the current steering circuit. Furthermore, the present disclosure could also eliminate the parasitic capacitance effect generated by the transistor in the second stage CS amplifier by adding the capacitor (or the neutralizing capacitor) between the differential pair transistors in the second stage CS amplifier. Therefore, the variable gain amplifier of the present disclosure can achieve low phase variations under different gains.

Although the present disclosure has been disclosed above through embodiments, the embodiments are not intended to limit the present disclosure. Persons with ordinary knowledge in the relevant technical field may make some changes and modifications without departing from the spirit and scope of the present disclosure. Therefore, the protection scope of the present disclosure shall be determined by the appended claims.

What is claimed is:

1. A variable gain amplifier, comprising:
a first stage common-source (CS) amplifier;
a second stage CS amplifier comprising a differential circuit and a current steering circuit, wherein the differential circuit and the current steering circuit are coupled to a common connecting node, and the current steering circuit draws at least part of a current flowing through the differential circuit from the common connecting node; and
a first transformer comprising a primary side and a secondary side, wherein a first terminal of the primary side is coupled to an output terminal of the first stage CS amplifier, a second terminal of the primary side is coupled to the common connecting node, a first terminal of the secondary side is coupled to a first differential input terminal of the differential circuit, and a second terminal of the secondary side is coupled to a second differential input terminal of the differential circuit.

2. The variable gain amplifier as claimed in claim 1, wherein the common connecting node is a virtual ground node.

3. The variable gain amplifier as claimed in claim 1, wherein the first stage CS amplifier comprises:
a first transistor, wherein a second terminal of the first transistor serves as the output terminal of the first stage CS amplifier; and
an input matching network comprising a first inductor, a matching capacitor, and a second inductor, wherein the first inductor is coupled between an input terminal of the first stage CS amplifier and a control terminal of the first transistor, the matching capacitor is coupled between the control terminal of the first transistor and a first terminal of the first transistor, and the second inductor is coupled between the first terminal of the first transistor and a ground terminal.

4. The variable gain amplifier as claimed in claim 1, wherein the differential circuit comprises:
a second transistor, wherein a first terminal of the second transistor is coupled to the common connecting node, a control terminal of the second transistor serves as the first differential input terminal of the differential circuit, and a second terminal of the second transistor serves as a first output terminal of the differential circuit; and
a third transistor, wherein a first terminal of the third transistor is coupled to the common connecting node, a control terminal of the third transistor serves as the second differential input terminal of the differential circuit, and a second terminal of the third transistor serves as a second output terminal of the differential circuit.

5. The variable gain amplifier as claimed in claim 4, wherein the current steering circuit comprises:
a fourth transistor, wherein a first terminal of the fourth transistor is coupled to the common connecting node, a control terminal of the fourth transistor is coupled to a control voltage, and a second terminal of the fourth transistor is coupled to a second terminal of the third transistor; and
a fifth transistor, wherein a first terminal of the fifth transistor is coupled to the common connecting node, a control terminal of the fifth transistor is coupled to the control voltage, and a second terminal of the fifth transistor is coupled to a second terminal of the second transistor.

6. The variable gain amplifier as claimed in claim 4, wherein the current steering circuit comprises:
a fourth transistor group comprising a plurality of fourth sub-transistors, wherein a first terminal of each of the fourth sub-transistors is coupled to the common connecting node, a control terminal of each of the fourth sub-transistors is coupled to a digital control signal, and a second terminal of each of the fourth sub-transistors is coupled to a second terminal of the third transistor; and
a fifth transistor group comprising a plurality of fifth sub-transistors, wherein a first terminal of each of the fifth sub-transistors is coupled to the common connecting node, a control terminal of each of the fifth sub-transistors is coupled to the digital control signal, and a second terminal of each of the fifth sub-transistors is coupled to a second terminal of the second transistor.

7. The variable gain amplifier as claimed in claim 5, wherein the second stage CS amplifier further comprises:
a first capacitor, wherein a first terminal of the first capacitor is coupled to the control terminal of the second transistor, a second terminal of the first capacitor is coupled to the second terminal of the third transistor and the second terminal of the fourth transistor; and
a second capacitor, wherein a first terminal of the second capacitor is coupled to the control terminal of the third transistor, and a second terminal of the second capacitor is coupled to the second terminal of the second transistor and the second terminal of the fifth transistor.

8. The variable gain amplifier as claimed in claim 1, further comprising:
a second transformer coupled to a first output terminal of the differential circuit and a second output terminal of the differential circuit.

9. An operation method of a variable gain amplifier, wherein the variable gain amplifier comprises a first stage CS amplifier, a second stage CS amplifier, and a first transformer, the first transformer is coupled between the first stage CS amplifier and the second stage CS amplifier, and the operation method comprises:
configuring a differential circuit and a current steering circuit in the second stage CS amplifier, wherein the differential circuit and the current steering circuit are coupled to a common connecting node, and the common connecting node is a virtual ground node;
drawing at least part of a current flowing through the differential circuit from the common connecting node using the current steering circuit; and
changing a gain of the variable gain amplifier according to a current amount drawn by the current steering circuit.

10. The operation method as claimed in claim 9, wherein drawing at least part of the current flowing through the differential circuit from the common connecting node using the current steering circuit comprises:
controlling a current drawn by the current steering circuit using a control voltage; and
changing the current flowing through the differential circuit according to the current drawn by the current steering circuit.

11. The operation method as claimed in claim 9, further comprising:
configuring a first capacitor and a second capacitor in the second stage CS amplifier, wherein a first terminal of the first capacitor is coupled to a first differential input terminal of the differential circuit, and a second terminal of the first capacitor is coupled to a second output terminal of the differential circuit and a first output terminal of the current steering circuit, wherein a first terminal of the second capacitor is coupled to a second differential input terminal of the differential circuit, and a second terminal of the second capacitor is coupled to a first output terminal of the differential circuit and a second output terminal of the current steering circuit; and
eliminating parasitic capacitance values in the differential circuit and the current steering circuit using the first capacitor and the second capacitor.

12. The operation method as claimed in claim 9, wherein the current steering circuit comprises a plurality of sub-transistors, and the operation method further comprises:
controlling a conduction state of each of the sub-transistors using a digital control signal, so that the current steering circuit draws currents of different current values from the common connecting node; and
changing a gain of the variable gain amplifier according to the currents of the different current values drawn by the current steering circuit.

13. The operation method as claimed in claim 9, further comprising:
operating the second stage CS amplifier at an operating voltage, wherein the operating voltage is less than or equal to 1 volt.
